(19) United States
(12) Patent Application Publication
(10) Pub. No.: US 2009/0250696 A1
(43) Pub. Date: Oct. 8, 2009

(54) NEAR NATURAL BREAKDOWN DEVICE

(76) Inventors: Guy Silver, Cupertino, CA (US); Juinerong Wu, Cupertino, CA (US)

Correspondence Address: Haynes and Boone, LLP;IP Section, 2323 Victory Avenue, SUITE 700, Dallas, TX, 75219, US

(21) Appl. No.: 12/303,365

(22) PCT Filed: Jun. 4, 2007
(86) PCT No.: PCT/US07/13191

§ 371 Date: Dec. 3, 2008

Related U.S. Application Data
(63) Continuation-in-part of application No. 11/446,699, filed on Jun. 4, 2006.

(51) Int. Cl. H01L 29/66

(52) U.S. Cl. 257/46; 257/E29.166

(57) ABSTRACT

A semiconductor device includes a semiconductor region wherein the semiconductor region is a forced or non-forced Near Natural breakdown region, which is completely depleted when a predetermined voltage having a magnitude less than or equal to the breakdown voltage of a non-Natural breakdown (for example, Zener breakdown and Avalanche breakdown) is applied across the device.

### CROSS-REFERENCE TO RELATED APPLICATIONS

The present application claims priority of U.S. patent application Ser. No. 11/446,699, filed Jun. 4, 2006, entitled “Near Natural Breakdown Device,” which is hereby incorporated by reference in its entirety. For the U.S. designation, the present application is a continuation of the aforementioned U.S. patent application Ser. No. 11/446,699 which is a continuation-in-part of the U.S. patent application Ser. No. 10/963,357, filed Oct. 12, 2004, entitled “EM Rectifying Antenna Suitable For Use In Conjunction With A Natural Breakdown Device,” which is also hereby incorporated by reference in its entirety.

### BACKGROUND OF THE INVENTION

1. Field of the Invention

The present invention relates to semiconductor devices that utilize a bias voltage to create a natural breakdown condition in a semiconductor region of the devices for applications including high speed switching and oscillator applications. At zero bias, the semiconductor region of the devices has a near natural breakdown condition. After biased, the region is in natural breakdown condition (fully depleted) causing devices conduct current. One example of a semiconductor device having a near natural breakdown condition is disclosed in U.S. patent application Ser. No. 10/963,357, entitled “EM Rectifying Antenna Suitable for use in Conjunction with a Natural Breakdown Device,” filed on Oct. 12, 2004 (“Copending Application”).

2. Discussion of the Related Art

FIG. 2 shows the current versus voltage characteristics of a conventional pn junction diode. FIG. 1 is a schematic representation of conventional abrupt pn junction diode 100. As shown in FIG. 1, conventional pn junction diode 100 includes p-region 101 and n-region 102. P-region 101 may be doped, for example, using a p-type dopant (i.e., electron acceptor, such as boron) and n-region 102 may be doped using an n-type dopant (i.e., an electron donor, such as phosphorus). Near the abrupt junction between p-region 101 and n-region 102, equilibrium due to the difference in electrochemical potentials of the two regions and the diffusion of charge carriers (e.g., electrons and “holes”) between the two regions deplete the charge carriers to form “depletion” regions 103 and 104 in p-region 101 and n-region 102, respectively. Under a so-called “abrupt junction approximation”, the widths xₚ of depletion region 103 and xₙ for depletion region 104, with an externally imposed voltage V across the pn junction, are given, respectively by:

$${x}_{n} = \sqrt{\frac{2 {ɛ}_{s} {N}_{A} ( {φ}_{i} - V )}{{qN}_{D} ( {N}_{A} + {N}_{D} )}}$$

$${x}_{p} = \sqrt{\frac{2 {ɛ}_{s} {N}_{D} ( {φ}_{i} - V )}{{qN}_{A} ( {N}_{A} + {N}_{D} )}}$$

where εₛ is the electrical permittivity of silicon, q is the charge of an electron, φᵢ is the “built-in” potential of the pn junction, N_{A} and N_{D} are the doping concentrations of p-region 101 and n-region 102, respectively.

As shown in FIG. 2, the horizontal axis shows the voltage V across the pn junction, and the vertical axis shows the diode current I_{D} across the pn junction. As shown in FIG. 2, when voltage V across the pn junction is greater than zero volts and greater than voltage Vₜₕ (the “threshold voltage”), the pn junction is strongly “forward biased” and the diode current I_{D} grows exponentially with the voltage V. When the voltage V across the pn junction is less than 0 volts, but not less than the voltage V_{br} (the “breakdown voltage”), the pn junction is “reverse biased” and the diode current I_{D} is very small. Under reverse bias, as the voltage grows in magnitude, the carriers generated increases in energy, leading to the breakdown phenomena¹, for example, tunneling and impact ionization at voltage V_{br}. At voltage V_{br}, the diode current I_{D} becomes very large and the diode has “broken down.” At breakdown, the magnitude of the average electrical field (in volts per centimeter) across the pn junction is given by the empirical expression: ¹ In this disclosure, the term “non-natural breakdown” is used to refer to breakdown phenomena, as distinguished from the “natural breakdown” and “near natural breakdown” phenomena described in the detailed description below.

$$\vert {E}_{br} \vert = \frac{4.0 \times {10}^{5}}{1 - \frac{1}{3} log \frac{{N}_{D}}{{10}^{16}}}$$

where N_{D} is the lesser of N_{A} and N_{B}.

### SUMMARY

The present invention provides a “near natural breakdown condition” that creates a natural breakdown condition on semiconductor devices when a bias voltage is applied. The natural breakdown condition is used for current conduction or switching applications. A “near natural breakdown device” (“NNBD”) has new active regions which achieve natural breakdown conditions when biased. In one embodiment of the present invention, the NNBD is a two-terminal near natural breakdown device. An NNBD may be used in high-speed oscillator and switching applications.

According to one embodiment of the present invention, a semiconductor device and a method for forming an NNBD are disclosed. The semiconductor device includes a semiconductor region formed adjacent a second region, wherein the first semiconductor region is a forced or non-forced near natural breakdown device, which is completely depleted when a predetermined voltage having a magnitude less than or equal to the non-natural breakdown voltage of, for example, Zener breakdown and Avalanche breakdown. The non-natural breakdown voltage is applied across the first and second regions. The second region may be a semiconductor material of a second conductivity type opposite in polarity to the first conductivity type. Alternatively, the second region may be a metal forming a schottky barrier to the first region. Further, the semiconductor device may include a third region adjacent the second region, the second region and the third region both comprising semiconductor materials, such that the first region, the second region and the third region form a bipolar transistor. In such a bipolar transistor, the first region may be an emitter or a collector of the bipolar transistor.

NNBD devices including a P-I-N type diode structure, a MOSFET, and a JFET structure are also possible.

The present invention is better understood upon consideration of the detailed description below and the accompanying drawings.

### BRIEF DESCRIPTION OF THE DRAWINGS

FIG. 1 is a schematic representation of conventional pn junction diode 100.

FIG. 2 shows the current (I) versus voltage (V) characteristics of a conventional pn junction diode.

FIG. 3 is a schematic representation of a forced near natural breakdown device (NNBD) 300, having a P-type region that is in a near natural breakdown condition before a natural breakdown voltage V_{fbr} is applied, according to one embodiment of the present invention.

FIG. 4 shows the current-voltage (IV) characteristics of NNBD 300.

FIG. 5(a) is a schematic representation of NNBD 500, an NPN transistor having a collector semiconductor region in near natural breakdown condition before a natural breakdown voltage V_{fbr NPN} is applied, according to one embodiment of the present invention.

FIG. 5(b) shows an expanded view of NNBD 500 when collector semiconductor region 501 is fully depleted under the natural breakdown condition.

FIG. 5(c) is a schematic representation of NNBD 510, a PNP transistor having a collector semiconductor region in near natural breakdown condition before a natural breakdown voltage V_{fbr PNP} V_{fbr NPN}, according to one embodiment of the present invention.

FIG. 5(d) shows an expanded view of NNBD 510 when collector semiconductor region 511 is fully depleted under the natural breakdown condition.

FIG. 5(e) shows the collector current I_{C} versus V_{CE} IV curve for a bipolar transistor.

FIG. 5(f) is a schematic representation of NNBD 520, an NPN transistor having an emitter semiconductor region in near natural breakdown condition before a natural breakdown voltage V_{fbr} applied, according to one embodiment of the present invention.

FIG. 5(g) shows an expanded view of NNBD 520 when the emitter semiconductor region is fully depleted under the natural breakdown condition.

FIG. 5(h) is a schematic representation of NNBD 530, an NPN transistor having both collector and emitter semiconductor regions in near natural breakdown condition before natural breakdown voltages are applied, according to one embodiment of the present invention.

FIG. 5(i) shows an expanded view of NNBD 530 when both collector and emitter semiconductor regions are fully depleted under the natural breakdown condition.

FIG. 5(j) is a schematic representation of NNBD 540, a PNP transistor having an emitter semiconductor region in near natural breakdown condition before a natural breakdown voltage V_{fbr} is applied, according to one embodiment of the present invention.

FIG. 5(k) shows an expanded view of NNBD 540 when the emitter semiconductor region is fully depleted under the natural breakdown condition.

FIG. 5(l) is a schematic representation of NNBD 550, a PNP transistor having both collector and emitter semiconductor regions in near natural breakdown condition before natural breakdown voltages are applied and an expanded view when both collector and emitter semiconductor regions are fully depleted under the natural breakdown condition, according to one embodiment of the present invention.

FIG. 6(a) is a schematic representation of NNBD 600, having an N-type region that is fully depleted at a reverse natural breakdown voltage V_{fbr}, according to one embodiment of the present invention.

FIG. 6(b) shows the current-voltage (IV) characteristics of NNBD 600.

FIG. 6(c) is a schematic representation of NNBD 600, having an N-type region that is fully depleted at a reverse Natural breakdown voltage V_{fbr}, according to one embodiment of the present invention.

FIG. 7(a) is a schematic representation of NNBD 700 at zero applied bias voltage and at a reverse bias voltage of V_{fbr}, according to one embodiment of the present invention; NNBD 700 represents a forced near natural breakdown N-Schottky diode under a forced near natural breakdown condition.

FIG. 7(b) is a schematic representation of NNBD 710 at zero applied bias voltage and at reverse bias voltage of V_{fbr}, according to one embodiment of the present invention; NNBD 710 represents a forced near natural breakdown P-Schottky diode under a forced near natural breakdown condition.

FIGS. 8(a) and 8(c) show NNBD 800 and NNBD 820 each including one forced near natural breakdown region adjacent to a contact at zero bias voltage bias and at a natural breakdown voltage V_{fbr}.

FIGS. 8(b) and 8(d) show NNBD 810 and NNBD 830 each including two forced near natural breakdown regions each adjacent to a contact at zero bias voltage bias and at a natural breakdown voltage V_{fbr}.

FIG. 9 shows a table of NNBD structures and characteristics under bias voltage, according to the present invention.

FIG. 10 (a) shows IV curve of NNBD 300 in forward current and forward bias voltage, when the V_{fbr} is at its smallest bias voltage (near-zero) to create a natural breakdown condition on p-region 301.

FIG. 10 (b) shows IV curve of NNBD 300 in reverse current and reverse bias voltage, when the V_{fbr} is at its smallest bias voltage (near-zero) to create a natural breakdown condition on p-region 301.

FIG. 11(a) shows a schematic representation of NNBD 1100, which is a NNBD P-I-N diode having a P-type near natural breakdown region, according to one embodiment of the present invention.

FIG. 11(b) shows a schematic representation of NNBD 1110, which is a NNBD P-I-N diode having an N-type near natural breakdown region, according to one embodiment of the present invention.

FIG. 11(c) shows a schematic representation of NNBD 1120, which is a NNBD P-I-N diode having both a P-type near natural breakdown region and an N-type near natural breakdown region, according to one embodiment of the present invention.

FIG. 12 shows a schematic representation of NNBD 1200, which is a NNBD MOSFET transistor having a near natural breakdown region adjacent a source contact, according to one embodiment of the present invention.

FIG. 13 shows schematic representation of NNBD 1300, which is a NNBD MOSFET transistor having a near natural breakdown region adjacent a drain contact, according to one embodiment of the present invention.

FIG. 14 shows a schematic representation of NNBD 1400, which is a NNBD JFET transistor having a near natural breakdown region adjacent a drain contact, according to one embodiment of the present invention.

FIG. 15 shows a schematic representation of NNBD 1500, which is a NNBD JFET transistor having a near natural breakdown region adjacent to a source contact, according to one embodiment of the present invention.

FIG. 16 shows a schematic representation of NNBD 1600, which is a NNBD JFET transistor having a near natural breakdown region adjacent a drain contact, according to one embodiment of the present invention.

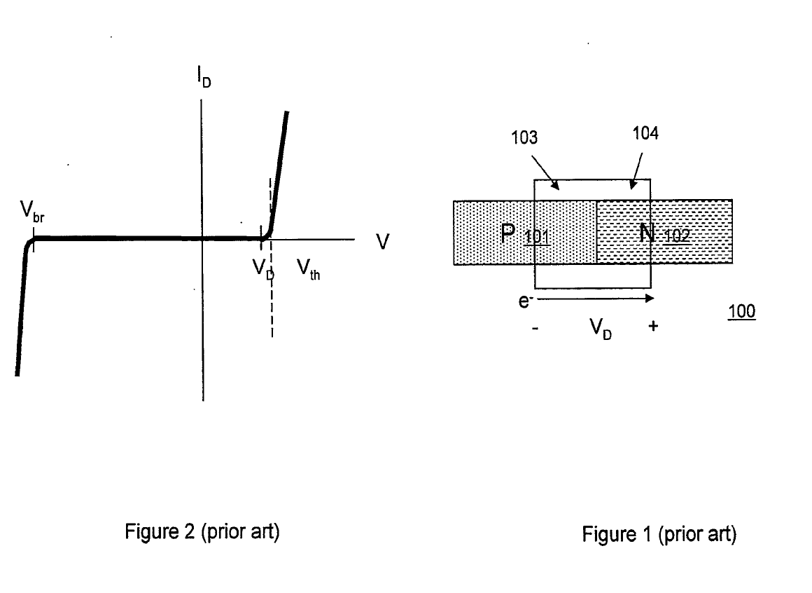

To facilitate comparison between the figures, like elements are assigned like reference numerals.

### DETAILED DESCRIPTION OF THE PREFERRED EMBODIMENTS

The following detailed description refers to a p-type or n-type region as fully depleted when the entire region is depleted of its majority carriers. This region may include different materials in any suitable forms, shapes, dimensions, layers, structures, conductivities or concentrations. Although the examples and drawings shown herein for NNBDs show regions of homogeneous or uniform dopant concentrations, such regions are only provided for illustration purpose only. The present invention is equally applicable in semiconductor devices for which the dopant concentrations in its various regions are non-homogeneous or non-uniform. In addition, this invention may be applied to devices with heterojunctions.

As described in the Co-pending Application, a semiconductor device (“NBD”) is in a “natural breakdown” condition when one of its semiconductor regions (P-type or N-type) is fully depleted without application of an external bias voltage. The present invention introduces the “near natural breakdown” condition. A semiconductor device is said to be in a “near natural breakdown” condition when a semiconductor region (P-type or N-type) on the semiconductor device, while it is not fully depleted at zero bias, becomes fully depleted when a specific bias voltage is applied (i.e., the semiconductor region of a semiconductor device changes from a “near natural breakdown” condition to a “natural breakdown” condition when a non-zero bias voltage is applied to the device). The non-zero bias voltage is a voltage level at which current conduction occurs and may be used as a switching voltage. A semiconductor device having a semiconductor region in a near natural breakdown condition is a “near natural breakdown device” (NNBD).

According to the present invention, the near natural breakdown condition can be applied on conventional or new semiconductor devices to create new characteristics. New devices may be created by utilizing the near natural breakdown condition.

The near natural breakdown condition may be applied to semiconductor device structures that operate under “non-natural breakdown” conditions. Examples of these semiconductor devices include tunneling (i.e. Zener effect) or impact ionization (i.e. avalanche effect) devices. The breakdown voltage of a near natural breakdown device is smaller or equal in magnitude to any non-natural breakdown voltage. Using the technique described below, a semiconductor device may be made to have its natural breakdown voltage coincide with a non-natural breakdown voltage. Using equation-P/equation-N discussed below or other formulas known to those skilled in the art, the natural breakdown voltage range can be calculated. When a device has a near natural breakdown voltage that is smaller in magnitude than the breakdown voltage of the device's “non-natural breakdown” voltage, the device experiences a natural breakdown instead of the “non-natural breakdown.” When the device's natural breakdown voltage coincides with its “non-natural breakdown voltage, the same breakdown phenomena may occur at the same time and currents due to both phenomena may occur, such that the total current exceeds those due to either breakdown effect. For example, a semiconductor device having a Zener breakdown voltage may be designed to have a semiconductor region with a near natural breakdown condition (i.e., a near natural breakdown Zener device) that becomes a natural breakdown voltage at the Zener breakdown voltage. In such a device, at the Zener breakdown voltage, the device experiences the combined breakdown effects. The device may switch faster and may produce a stronger current than a Zener device. Combined effects of avalanche breakdown and Natural breakdown may be applied on semiconductor devices. Therefore, a near natural breakdown condition can be designed in a semiconductor device to create a fully depleted region at a natural breakdown voltage varies from near-zero to the “non-natural breakdown” voltage (in magnitude) for that device.

The near natural breakdown condition may be implemented on conventional or new semiconductor device structures. In one embodiment, the implementation steps may be: (1) selecting a natural breakdown voltage V_{fbr}, (2) selecting a semiconductor region and doping concentration within the device to create a near natural breakdown condition at zero bias, (3) using the doping concentration to calculate the width of the semiconductor region using equation-N/equation-P or other formulas known to those skilled in the art. (Simulation could also be used for determining the width.) These steps may be used for semiconductor devices that have a non-natural breakdown voltage as well. The natural breakdown voltage V_{fbr} (determined according to step (1) above) and the non-natural breakdown voltage determines whether the device breakdowns under a non-natural breakdown condition or a natural breakdown condition. For a device that does not breakdown under a non-natural breakdown condition during its normal intended operations, the width of such a region (i.e., the natural breakdown region) may be selected up to the maximum width for such a region to still experience a near natural breakdown condition. Therefore, the maximum natural breakdown voltage can be calculated from the doping concentration and width of the region. After selecting a suitable natural breakdown bias voltage for an application, the width of the device may be calculated by solving equation-P/equation-N or other formulas known to those skilled in the art and from the selected natural breakdown bias voltage and semiconductor doping concentrations. For devices that experience a non-natural breakdown, the maximum natural breakdown voltage is the non-natural breakdown voltage.

The near natural breakdown condition may be implemented to provide devices with a wider range of breakdown voltages, low voltage high speed switching, voltage protection or regulation, switching, prevent undesired breakdown, provides a current and combine other breakdown effects with a natural breakdown.

According to one embodiment of the present invention, a pn-junction diode that has a non-natural breakdown includes a semiconductor region (say, p-type region) that has a width wₚ that is less than or equal to the depletion width xₚ of a conventional abrupt pn-junction of comparable dimensions and comparable dopant concentrations, when an externally imposed non-Natural breakdown voltage of V_{br}. The V_{br} voltage is the largest bias voltage that can be imposed across the pn-junction before a region of the conventional abrupt pn-junction diode enters a non-natural breakdown condition due to, for example, tunneling (i.e. Zener effect) or impact ionization (i.e. avalanche effect). That is:

$${w}_{p} < {x}_{p} = \sqrt{\frac{2 {ɛ}_{s} {N}_{D} ( {φ}_{i} - {V}_{br} )}{{qN}_{A} ( {N}_{A} + {N}_{D} )}}$$

where εₛ is the electrical permittivity of silicon, q is the charge of an electron, φᵢ is the “built-in” potential of the pn junction, N_{A} and N_{D} are the doping concentrations of p-region 101 and n-region 102, respectively. When wₚ=xₚ (wₙ=xₙ, for n-type region), the region is referred to as a non-forced near natural breakdown region, and when wₚ<xₚ (wₙ<Xₙ, for n-type region), the region is referred to as a “forced near natural breakdown” region.

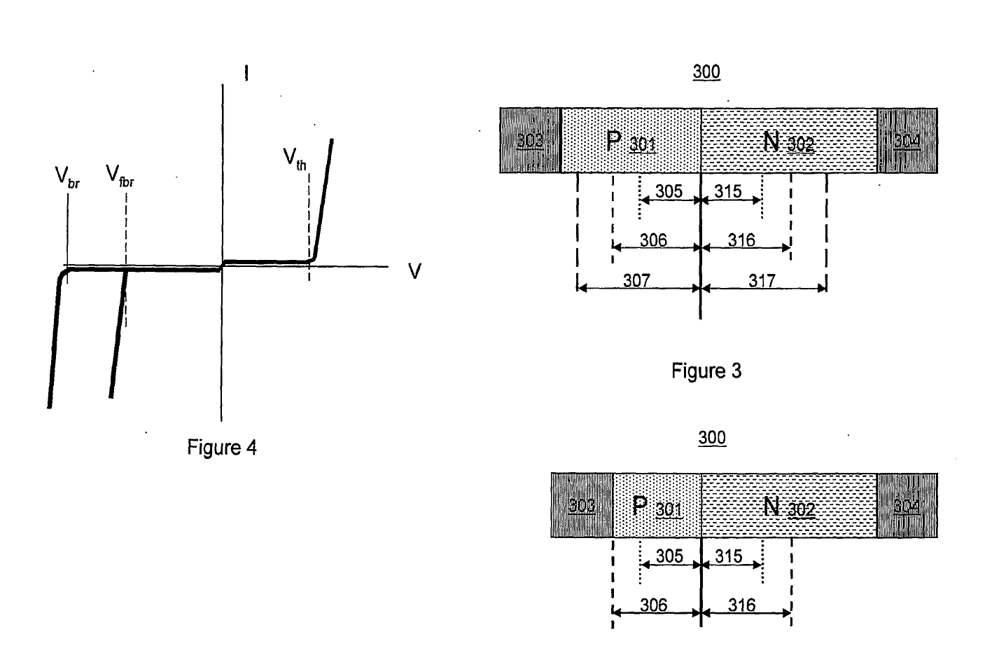

FIG. 3 is a schematic representation of NNBD 300, according to one embodiment of the present invention. As shown in FIG. 3, NNBD 300 includes p-region 301 and n-region 302, with p-region 301 having a depletion width 305, p-region width 306 (wₚ), which is less than or equal to xₚ of a corresponding depletion width in the p-region of a conventional pn junction of comparable dimensions and dopant concentrations, when an external non-Natural bias breakdown voltage of V_{br} is imposed. The depletion width xₚ of the p-region 301 at non-natural breakdown voltage is indicated in FIG. 3 by length 307 for reference. (A semiconductor region having a depletion width that is less than the depletion width for the corresponding semiconductor region in a conventional pn junction, when an externally imposed non-natural breakdown voltage of V_{br} is imposed is referred herein as having a “forced breakdown” width. A semiconductor region having a depletion width that is equal to the depletion width for the corresponding semiconductor region in a conventional pn junction, when an externally imposed non-Natural breakdown voltage of V_{br} is imposed is referred herein as having a “non-forced Near Natural breakdown” width). In contrast, the width of n-region 302 may be smaller than, greater than or equal to the depletion region xₙ for the n-region of a conventional pn junction diode of comparable doping concentrations and dimensions, when an externally imposed reverse non-natural breakdown voltage of V_{br} is imposed. The depletion width xₙ of the n-region 302 at non-Natural breakdown voltage is indicated in FIG. 3 by length 317 for reference.

One embodiment of the present invention is a forced near natural breakdown condition on p-region 301, and n-region 302 having a width greater than xₙ. Also shown are contact regions 303 and 304 which allow NNBD 300 to be connected to an electronic circuit. The doping concentrations in p-region 301 and n-region 302 are sufficiently high such that contacts 303 and 304 are ohmic contacts. Contact region 303 and 304 may be connected, for example, by depositing a conventional interconnect conductor (e.g., aluminum or copper) using conventional chemical vapor deposition techniques, or other means known to those skilled in the art. P-region 301 and n-region 302 may be formed in a conventional silicon substrate using ion implantation, or other means known to those skilled in the art.

P-region width wₚ of an NNBD 300 may be calculated based upon the doping concentration, depletion width, Natural breakdown voltage and non-Natural breakdown voltage. Suitable width wₚ for NNBD 300 may be calculated using the following steps:

(1) First choose doping concentrations for a p-region and an n-region of a conventional PN junction diode such that, under the zero applied bias voltage, the p-region has a depletion width Zₚ (indicated by width 305 of FIG. 3) and the n-region has a depletion width Zₙ (indicated by width 315 of FIG. 3). (Depletion width of the p-region and n-region may be used to choose appropriate doping concentrations). These dimensions create a built-in voltage V_{built-in} in the conventional pn junction diode when no external voltage is imposed across the pn junction. Also when the conventional PN junction diode is externally imposed by a reverse bias voltage equal to the non-natural breakdown voltage V_{br}, the p-region has a depletion width xₚ and the n-region has a depletion width xₙ. Depletion width xₚ of the non-natural breakdown condition is the maximum width of wₚ. Width wₚ is larger than Zₚ. In a forced NNBD, the magnitude of the natural breakdown voltage V_{fbr} is less than the magnitude of V_{br}. In a non-forced NNBD, the bias Natural breakdown voltage V_{fbr} is equal to the V_{br}.

(2) Select the desired Natural breakdown voltage V_{fbr} for NNBD between zero bias and the non-Natural breakdown voltage V_{br} of the device. When the applied bias voltage is between zero and V_{fbr}, only a leakage current will flow through the NNBD. However, when the applied bias voltage has a magnitude greater than V_{fbr}, a larger majority carrier reverse current will flow through the NNBD. Natural breakdown condition occurs when the NNBD is biased to selected natural breakdown voltage V_{fbr}.

(3) Calculate the depletion width wₚ for p-region 301 such that, when voltage V_{fbr} is imposed between contact 303 and contact 304, the entire p-region 301 becomes completely depleted. Assuming an abrupt junction approximation, the width wₚ may be calculated using the following equation-P:

$${w}_{p} = \sqrt{\frac{2 {ɛ}_{s} {N}_{D} ( {φ}_{i} - {V}_{fbr} )}{{qN}_{A} ( {N}_{A} + {N}_{D} )}}$$

There are other ways to calculate wₚ, as known by those skilled in the art. When wₚ=xₚ, V_{fbr} equals V_{br}. Doping concentrations may be represented by number of carriers. Width wₚ for NNBD 300 may also be calculated by other steps, for example: (1) Choosing a desired natural breakdown voltage V_{fbr}; (2) choosing doping concentrations and depletion width Zₚ; and (3) use equation-P mentioned above (or other formulas known to those skilled in the art) to calculate width wₚ. When a semiconductor device that does not experience a non-natural breakdown condition within the semiconductor region to be fully depleted, the maximum width of wₚ is the semiconductor region width and width wₚ is greater than Zₚ.

Note that width wₚ is calculated above using an abrupt junction approximation. Other suitable methods may also be used. Width wₚ may be calculated using a different junction approximation, depending on the application. As explained above, the condition wₚ<xₚ is referred to as a “forced near natural breakdown condition” and, under such a condition, p-region 301 is referred to as a “forced near natural breakdown region”, according to one embodiment of the present invention. When p-region 301 is in a forced near natural breakdown condition, the value of V_{fbr} is less than V_{br}. The condition wₚ=xₚ, is referred to as a “non-forced near natural breakdown condition” and, under such a condition, p-region 301 is referred to as a “non-forced near natural breakdown region”, according to another embodiment of the present invention. When NNBD has a “non-forced near natural breakdown region”, Natural breakdown and non-natural breakdown will occur and produce significant current.

Once wₚ is determined, an NNBD may be created with any suitable width of n-region 302, such that p-region 301 will be fully depleted between contact region 303 and n-region 302 when NNBD 300 is biased at V_{fbr}. Wₙ (indicated by width 316) is the depletion region width of n-region 302 on NNBD 300 when NNBD 300 is reverse biased to V_{fbr}. The width of n-region 302 may range from wₙ to larger than xₙ as long as n-region 302 does not become completely depleted prior to p-region 301 becoming completely depleted. When the external voltage applied between contacts 303 and 304 is −V_{fbr}, p-region 301 of NNBD 300 is fully depleted. One embodiment of the invention provides a forced Near Natural breakdown condition on p-region 301 with wₚ less than xₚ and the width of n-region 302 being a value between wₙ to larger than xₙ. One embodiment of the invention is a non-forced Near Natural breakdown condition in which p-region 301 has width wₙ that is equal to xₚ and the width of n-region 302 may range from wₙ to larger than xₙ.

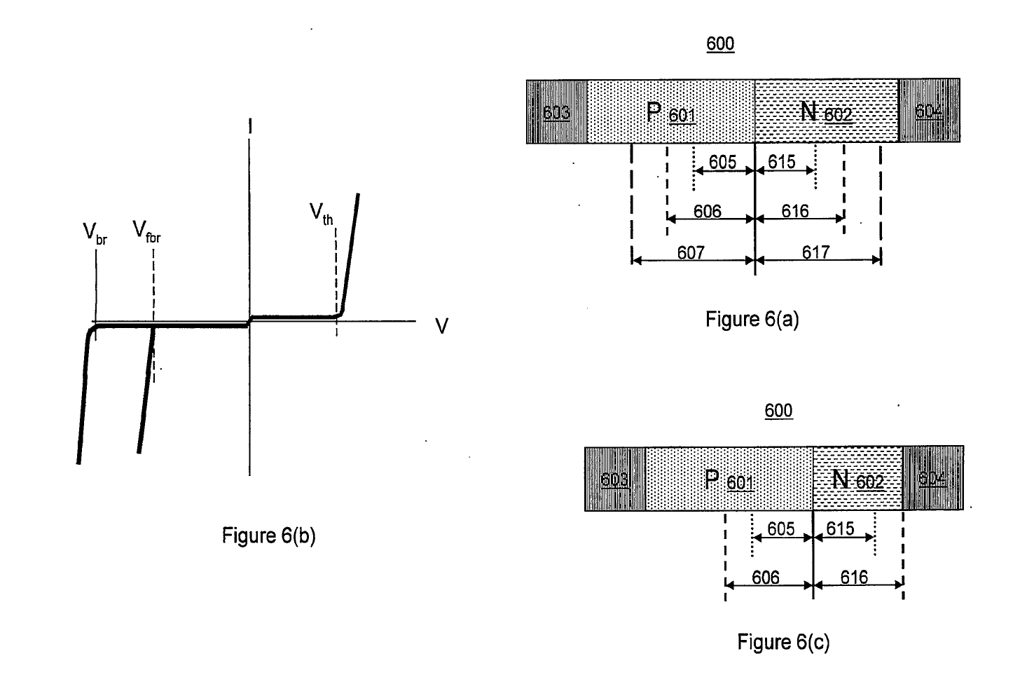

In another embodiment of the present invention, shown in FIG. 6(a), n-region 602 may be put under a forced near natural breakdown condition without a near natural breakdown condition in p-region 601 of NNBD 600. An NNBD may have more than one breakdown region. In this embodiment the width of p-region 601 may range from wₚ to larger than xₚ as long as p-region 601 does not become completely depleted when n-region 602 becoming completely depleted. In FIG. 6(a), the depletion width wₚ of p-region 601 and depletion width wₙ at Natural breakdown are indicated in FIG. 6(a) as widths 606 and 616, respectively. One embodiment of the invention provides a non-forced Near Natural breakdown n-region 602 (i.e., wₙ equals xₙ) and p-region 601, having a width between wₚ to larger than xₚ. Another embodiment of the invention provides a forced Near Natural breakdown condition on n-region 602 is created with wₙ smaller than xₙ and the width of p-region 601 having a width between wₚ to greater than xₚ. In this embodiment the width of p-region 601 may range from wₚ to larger than xₚ, as long as p-region 601 does not become completely depleted when n-region 602 becoming completely depleted. NNBDs having such a structure include forced near natural breakdown diodes. These NNBD regions can be either forced Near Natural breakdown regions or non-forced near natural breakdown regions.

Generally, an NNBD has one of the p-region or n-region fully depleted under a reverse bias of V_{fbr}. Once the NNBD has a fully depleted region, the electric field will force electrons, holes, or both, across the fully depleted region thus creating a current. For example, NNBD 300 of FIG. 3 has p-region 301 in a forced Near Natural breakdown condition and an n-region 302 with its width larger than xₙ. When NNBD 300 has an externally imposed reverse bias voltage of V_{fbr}, p-region 301 becomes fully depleted (i.e., the distance between contact 303 and the depletion region edge within p-region 301 becomes zero). Under that condition, due to the polarity of the electric field within p-region 301, electrons entering p-region 301 from contact region 303 are immediately swept across p-region 301 into n-region 302. Likewise holes entering the depletion region from n-region 302 are swept across p-region 301 into contact region 303.

Once the externally imposed reverse bias voltage across NNBD 300 reaches V_{fbr}, the depletion regions associated with p-region 301 and n-region 302 remain the same width even if the voltage is further increased. This is because there are no additional holes in p-region 301 available to deplete electrons from n-region 302. As a result, as the magnitude of the external imposed reverse bias voltage exceeds V_{fbr}, the additional voltage appears as a voltage drop in the neutral region of n-region 302. This induced voltage causes an electron current (i.e. reverse current) to flow from contact region 303 into n-type region 302.

When a forward bias voltage between zero and the threshold voltage (i.e., 0<V_{IN}<Vₜₕ) is imposed across NNBD 300, the depletion widths in both p-region 301 and n-region 302 reduce. The voltage drops across the depletion regions reduce also. In this regime, a small forward leakage current proportional to the external imposed voltage flows in NNBD 300. As the external imposed voltage approaches threshold voltage Vₜₕ, the depletion width in NNBD 300 becomes significantly smaller to allow a significant current to flow.

Once the externally imposed voltage exceeds the threshold voltage (i.e., V_{IN}>=Vₜₕ), NNBD 300 conducts a forward bias current.

When reverse biased, NNBD 300 operates as a majority carrier device (electrons being injected in to the n-region) as apposed to a minority carrier device when forward biased. The switching times of majority carrier devices are typically faster than switching times of minority carrier devices.

FIG. 4 is a plot of the current versus voltage (IV) characteristics of NNBD 300. NNBD 300 conducts appreciable reverse current when the externally imposed voltage is a reverse bias voltage is greater in magnitude than V_{fbr} and conduct forward current when the externally imposed voltage is larger than Vₜₕ. NNBD 300 conducts a negligible leakage current when the bias voltage is between V_{fbr} and Vₜₕ.

To summarize, an NNBD of the present invention allows a conductive current flow when a bias voltage greater than V_{fbr} is applied. At V_{fbr}, a semiconductor region of an NNBD has a Natural breakdown condition. Using a Near Natural breakdown condition on devices allows a wider and more flexible voltage range of conduction than achievable using non-Natural breakdown conditions, for example, Zener and Avalanche effects. The NNBD operates as a majority carrier device when biased. If the applied bias voltage exceeds the threshold voltage V_{fbr}, the NNBD provides a conductive current. The application of the present NNBD invention to conventional PN junction diodes created a new range of active bias voltages; namely, the bias voltage less in magnitude than the V_{br}. This new active range enables NNBD-modified PN junction diodes to have two active regions that can be used for various applications, including oscillator circuits and high-speed switches.

According to another embodiment of the present invention, as discussed above, FIG. 6(a) shows NNBD 600 with n-type region 602 having a width wₙ that is less than xₙ (i.e., the depletion width of a conventional pn junction diode when imposed an external reverse non-Natural breakdown voltage V_{br}). Assuming an abrupt junction approximation, the width wₙ may be calculated using the following equation-N:

$${w}_{n} < {x}_{n} = \sqrt{\frac{2 {ɛ}_{s} {N}_{D} ( {φ}_{i} - {V}_{br} )}{{qN}_{A} ( {N}_{A} + {N}_{D} )}}$$

A similar determination provides width wₙ (indicated by width 616) for NNBD 600. When NNBD 600 is externally imposed reverse bias voltage V_{fbr}, n-region 602 becomes fully depleted (i.e., the distance between contact region 604 and the depletion region edge within n-region 602 becomes zero). Under that condition, holes entering n-region 602 from contact region 604 are immediately swept across n-region 602 into p-region 601. Likewise, electrons entering the depletion region from p-region 601 are be swept across n-region 602 into enter contact region 604.

Once NNBD 600 has an externally imposed reverse bias voltage of V_{fbr} the depletion region associated with n-region 602 and p-region 601 will not increase in width. This is because there are no available electrons in n-region 602 to deplete holes from p-region 601. Therefore as the magnitude of the external imposed reverse bias voltage is increased larger than V_{fbr}, a voltage will be induced within the neutral region of p-region 601. This induced voltage will cause a reverse current to flow from contact 604 into p-region 601 due to the sweeping effect of the depletion region's electric field just described.

When NNBD 600 is externally imposed with a forward bias voltage between zero and the threshold voltage (i.e., 0<V_{IN}<Vₜₕ), the depletion widths in both p-region 601 and n-region 602 reduce. The voltage drop across the depletion regions reduces also. In this regime, a small forward leakage current proportional to the external imposed voltage flows in NNBD 600. As the external imposed voltage becomes very close to Vₜₕ, the depletion width in NNBD 600 becomes significantly small to allow a significant current to flow. Once the externally imposed voltage exceeds the threshold voltage (i.e., V_{IN}>=Vₜₕ), NNBD 600 conducts current.

FIG. 6(b) is a plot of the current versus voltage characteristics of NNBD 600. Another embodiment according to the present invention provides wₙ=xₙ (i.e., the non-forced Near Natural breakdown depletion condition). Non-forced NNBD 600 has the same behavior as a non-forced NNBD 300.

When an external voltage V_{fbr} is imposed across NNBD 300 or 600, the voltage across the depletion region is equal to V_{fbr} plus the built-in potential V_{built-in}. Therefore, carriers that cross the depletion region are higher in potential by voltage V_{built-in} than the externally imposed voltage. To compensate for this voltage difference, an increase current equal to V_{built-in} divided by the total NNBD resistance flows through NNBD 300 or 600. This increase in current occurs so long as NNBD 300 p-region 301 or NNBD 600 n-region 602 is completely depleted. Having an increased current at the turn-on voltage may help in reducing the off-to-on and on-to-off switching times.

It is known in the art that there are no contact materials that create a true p-type ohmic contact. Instead a p-type Ohmic contact may be emulated using a p-type Schottky contact with a sufficiently thin depletion region. The thin depletion region allows tunneling, as it is created using a highly doped p-type material. Using a highly doped p-type material may be undesirable or may not provide a low enough resistance. The resistance at the contact/semiconductor junction is proportional to the junction's depletion region width. When NNBD 300 and NNBD 600 are reversed biased, emulated Ohmic contacts using schottky contacts are under forward bias. Forward biasing the schottky contacts reduce the contact depletion width, thereby increasing the contact tunneling capability. Increasing the tunneling capability reduces the ohmic contact resistance.

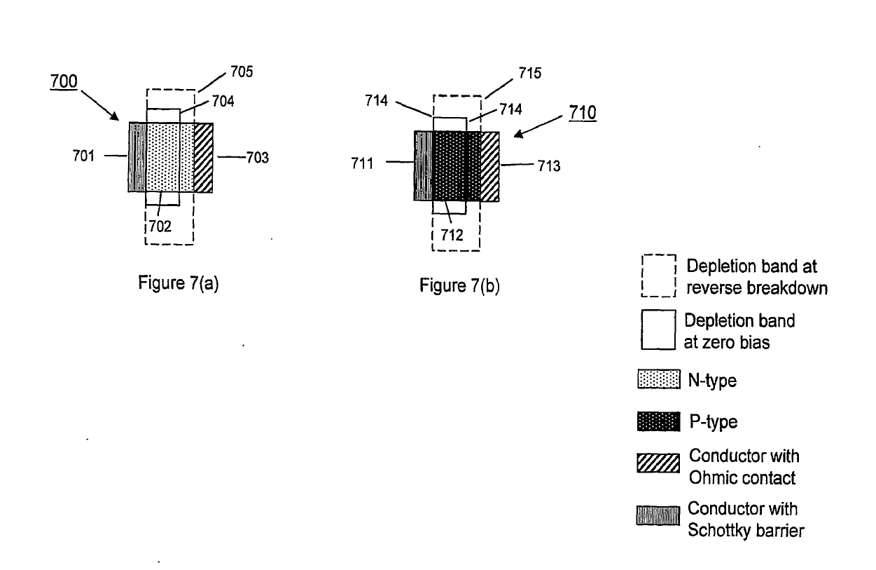

According to another embodiment of the present invention FIG. 7(a) shows NNBD 700 with n-region 702, at a zero applied bias voltage having depletion region 704, and at a reverse bias voltage of V_{fbr} having n-region 702 fully depleted, and conductors 701 and 703 which are contacts provided for connecting NNBD 700 to an electronic circuit. Voltage V_{fbr} is lesser in magnitude than the breakdown voltage V_{br} of a conventional n-Schottky diode using comparable material as NNBD 700. The doping concentration in n-region 702 is sufficiently high such that the junction between conductor 703 and n-region 702 is an ohmic contact and conductor 701 forms a Schottky barrier to n-region 702. In NNBD 700 at zero applied bias voltage, n-region 702 has a depletion width 704. When NNBD 700 is reverse biased to V_{fbr}, n-region 702 is fully depleted, having a depletion width 705. Once n-region 702 becomes fully depleted by a reverse biased voltage V_{fbr} across NNBD 700, the electric field associated with the depletion region in NNBD 700 sweeps electrons from contact 701 to contact 703, thereby resulting in a reverse current through NNBD 700. N-region 702 will remain fully depleted as long as a reverse biased voltage with a magnitude greater than or equal to V_{fbr} is imposed externally across NNBD 700. NNBD 700 under forward bias performs substantially the same as a conventional n-type Schottky diode of comparable materials and dimensions under forward biased conditions.

According to another embodiment of the present invention, FIG. 7(b) illustrates NNBD 710 with p-region 712, at a zero bias voltage having depletion region 714, and at a reverse bias voltage V_{fbr} having p-region 712 fully depleted, and conductors 711 and 713, which are contacts provided for connecting NNBD 710 to an electronic circuit. Voltage V_{fbr} is lesser in magnitude than a non-natural breakdown voltage V_{br} of a conventional p-Schottky diode of comparable material and dimension as NNBD 710. The doping concentration in p-region 712 is sufficiently high, such that the junction between conductor 713 and p-region 712 is an ohmic contact, and conductor 711 forms a Schottky barrier to p-region 712. In NNBD 710 at zero applied bias voltage, p-region 712 has a depletion width 714. When NNBD 710 is reverse biased to V_{fbr}, P-region 712 is fully depleted having a depletion width 715. Once p-region 712 becomes fully depleted, when NNBD 710 is reverse biased at V_{fbr}, the electric field associated with the NNBD 710 depletion region sweeps electrons from contact 713 to contact 711, thereby causing a reverse current through NNBD 710. P-region 712 is fully depleted as long as a reverse biased voltage with a magnitude greater than or equal to V_{fbr} is externally imposed on NNBD 710. NNBD 710 under forward bias performs substantially the same as a conventional p-type Schottky diode of comparable dimensions and materials under forward biased condition.

The following steps determine a forced near natural breakdown width for NNBD 700: (1) finding a non-natural breakdown voltage V_{br}, a depletion width xₙ at bias voltage V_{br}, and a depletion width Zₙ at zero bias of a conventional Schottky diode using an n-region doping concentration, (2) finding a reverse bias natural breakdown voltage V_{fbr} between zero and V_{br} (or equal to V_{br}) that can be used with Schottky diode 700, and (3) calculating the depletion width wₙ of n-region 702, such that, when a reverse natural breakdown bias voltage V_{fbr} is applied across NNBD 700, n-region 702 becomes fully depleted. Depletion width wₙ is between Zₙ and xₙ. Similar steps can be used to determine a forced near natural breakdown width for NNBD 710. Regions 702 and 712 include, respectively, multiple n-type and p-type-sections of different doping concentrations. NNBD 700 or 710 may be created in a similar method or other methods.

When an external voltage V_{fbr} is imposed across NNBD 700 or 710, the voltage across the depletion region is equal to V_{fbr} plus the built-in potential V_{built-in}. Therefore carriers that cross the depletion band region are higher in potential by V_{built-in} than the externally imposed voltage. To compensate for this voltage difference, an increase current equal to V_{built-in}/the total NNBD resistance flows through the NNBD. This increase in current occurs as long as n-region 702 of NNBD 700 or p-region 712 of NNBD 710 is completely depleted. Also NNBD 700 and 710 have no neutral regions when externally imposed by a voltage greater than or equal V_{fbr}. Having an increased current and no neutral region at V_{fbr} may help in reducing the off-to-on and on-to-off switching times.

The application of the technique provides a near natural breakdown condition to a conventional Schottky diode creates a new active bias voltage range; namely, the range of reverse bias voltages between zero and V_{br}. This new active region enables a near natural breakdown condition modified Schottky diode to have two active regions to be utilized for applications, including oscillator circuits and high-speed switches.

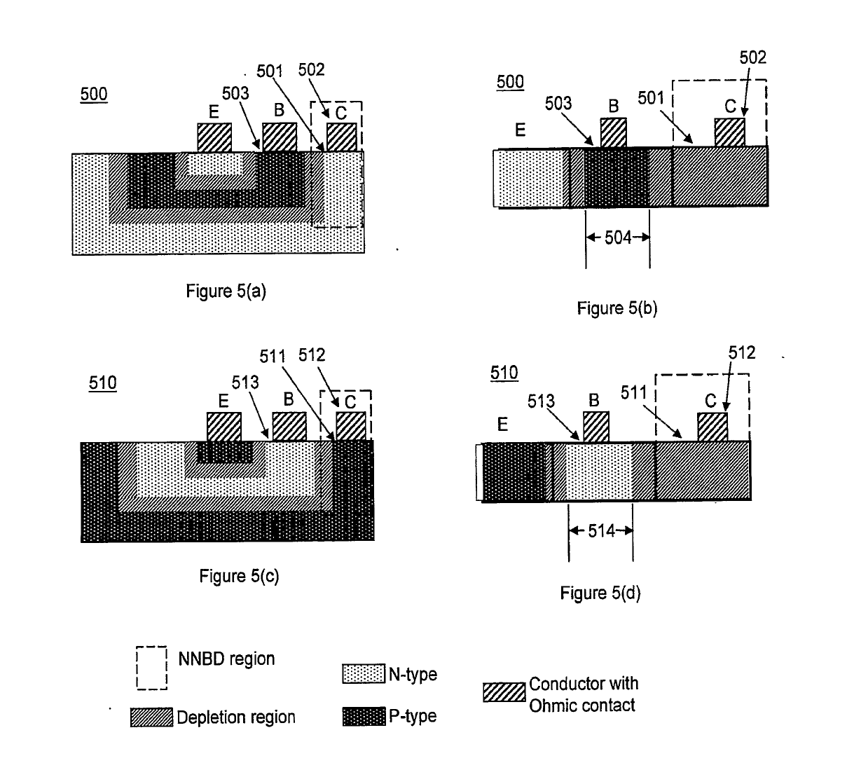

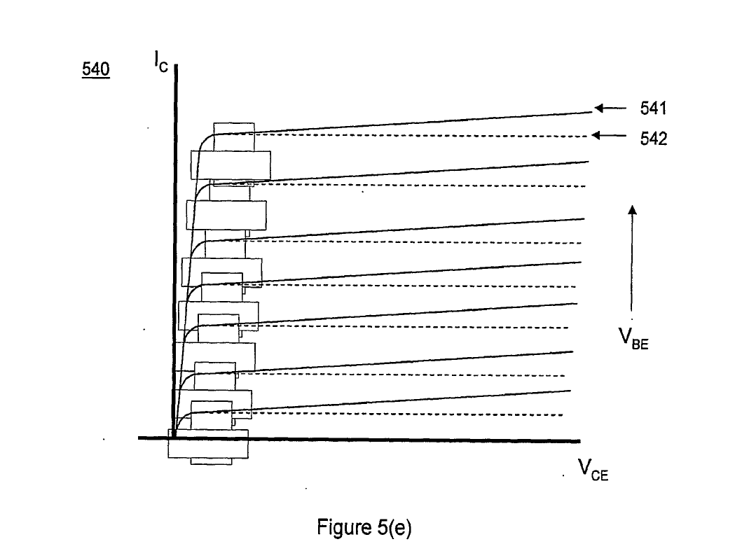

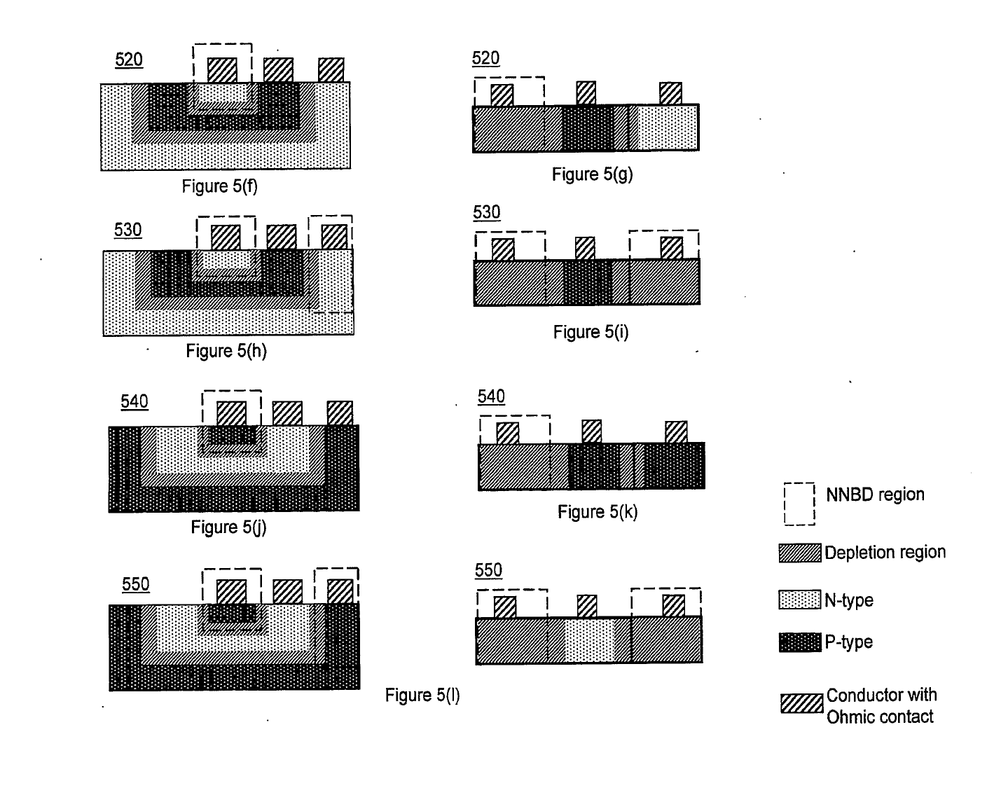

According to another embodiment of present invention, an NNBD may also be formed using three or more semiconductor regions, one or more of which is adjacent to a contact and becomes fully depleted when externally biased at a natural breakdown voltage. A semiconductor region may include multiple sections of the same polarity type. FIG. 5(a) shows NNBD 500, which is an NPN bipolar transistor having a collector semiconductor region 501 that is a natural breakdown region with a natural breakdown voltage V_{fbr NPN}. When a voltage V_{CB} that equals V_{fbr NPN} is imposed across collector region 501 and base region 503 of NNBD 500, collector semiconductor region 501 becomes fully depleted under collector contact 502 (i.e., collector region 501 is at the natural breakdown condition). FIG. 5(b) shows an expanded view of NNBD 500 when collector semiconductor region 501 is under the natural breakdown condition with base semiconductor region 503 having a neutral region 504. FIG. 5(c) shows NNBD 510, which is a PNP bipolar transistor having a collector semiconductor region 511 that is a natural breakdown region with a natural breakdown voltage V_{fbr PNP}. When a voltage V_{CB} that equals V_{fbr PNP} is imposed across collector region 511 and base region 513 of NNBD 510, collector semiconductor region 511 becomes fully depleted under collector contact 512 (i.e., collector region 511 is at the natural breakdown condition). FIG. 5(d) shows an expanded view of NNBD 510 when collector semiconductor region 511 is under the natural breakdown condition with base semiconductor region 513 having a neutral region width 514.

When a voltage V_{CB} that equals or is greater than V_{fbr} NPN is imposed across collector region 501 and base region 504 of NNBD 500, the depletion region width at the NNBD 500 collector base junction remains unchanged, as collector semiconductor region 501 is at the natural breakdown condition. Therefore, the width of the neutral region 504 in base region 503 of NNBD 500 does not change when voltage V_{CB} exceeds a value equal to or greater than V_{fbr NPN}. Having a base neutral region 504 width unaffected by V_{CB} in base region 503 causes an internal voltage difference across collector region 501 and base region 504. Two phenomena compensate for this internal voltage difference. First, an increase in collector current diminishes the internal voltage drop. Further, an electric field is created in neutral region 503 in base region 504 of NNBD 500. As in a conventional bipolar transistor operating in the forward active mode (i.e. base-emitter junction is forward biased, base-collector junction is reversed biased), the collector current is controlled by the injection of carriers into the base region from the emitter region based upon the V_{BE} voltage and the base current, independent of the V_{CB} voltage. Therefore, in NNBD 500, the electric field produced within the base neutral region is the dominant effect. Similar effects occur in NNBD 510, such that an electric field is also created in the neutral region of base 513 of NNBD 510.

A conventional bipolar transistor operating in the forward active mode has a variety of non-ideal effects and breakdown conditions, such as the Early effect which causes increased collector current due to the shrinking width in the base neutral region, as voltage increases. The Early effect can be seen from FIG. 5(e) which shows the collector current I_{C} versus V_{CE} IV curve for a bipolar transistor. In FIG. 5(e), the solid lines (i.e. 541) show the increase in collector current due to the Early effect for a conventional bipolar transistor. As explained above, the width of the neutral region 504 in base region 503 of NNBD 500 does not decrease as voltage V_{CB} increases. Consequently, NNBD 500 does not exhibit the collector current change of the Early effect. The dashed lines (i.e. 542) shown in FIG. 5(e) represent the collector current for a bipolar transistor with a collector semiconductor region being a near natural breakdown region (e.g., NNBD 500). Also a conventional bipolar transistor has a punch-through breakdown condition which occurs when the base region becomes fully depleted, as the base-collector depletion region increases until it reaches the base-emitter depletion region. NNBD 500 does not experience a punch-through breakdown condition. In a similar manner, NNBD 510 does not experience a punch-through breakdown condition.

When NNBD 500 operates in a cutoff mode (i.e. both the base-emitter and the base-collector junctions are reversed biased)—with collector semiconductor region 501 in a natural breakdown condition—the collector current from collector contact 502 enters the neutral region 504 of base region 503. However, the polarity of the electric field in the base-emitter depletion region prevents the current entering the base neutral region 504 from crossing the base-emitter junction. As a result, the collector current in NNBD 500 substantially flows out of the base contact. NNBD 510 operates similarly in cutoff mode as NNBD 500.

An NNBD may also be formed by a bipolar transistor with the emitter semiconductor region that becomes fully depleted when externally biased at a natural breakdown voltage. FIG. 5(f) shows NNBD 520, which is an NPN bipolar transistor having an emitter semiconductor region in near natural breakdown condition before a natural breakdown voltage V_{fbr} is applied. FIG. 5(g) shows an expanded view of NNBD 520 when the emitter semiconductor region is fully depleted under the natural breakdown condition with the base semiconductor region having a neutral region. FIG. 5(j) shows NNBD 540, which is a PNP bipolar transistor having an emitter semiconductor region in near natural breakdown condition before a natural breakdown voltage V_{fbr} is applied. FIG. 5(k) shows an expanded view of NNBD 540 when emitter semiconductor region is fully depleted under the natural breakdown condition with the base semiconductor region having a neutral region. When NNBD 520 or NNBD 540 operate in a cutoff mode when the emitter semiconductor region is fully depleted the emitter current substantially flows out of the base contact as discussed above.

An NNBD may also be formed by a bipolar transistor with both the collector and emitter semiconductor regions becoming fully depleted when externally biased at a natural breakdown voltage. FIG. 5(h) shows NNBD 530, which is an NPN transistor having collector and emitter semiconductor regions in near natural breakdown condition before natural breakdown voltages are applied. FIG. 5(i) shows an expanded view of NNBD 530 when both collector and emitter semiconductor regions are fully depleted under the natural breakdown condition with the base semiconductor region having a neutral region. FIG. 5(l) shows NNBD 550, which is a PNP transistor having both collector and emitter semiconductor regions in near natural breakdown condition before natural breakdown voltages are applied and an expanded view when both collector and emitter semiconductor regions are fully depleted under the natural breakdown condition. NNBD 530 and NNBD 550 will exhibit the combined effects of a bipolar transistor having a collector region in near natural breakdown condition and a bipolar transistor having an emitter semiconductor region in near natural breakdown condition as discussed above.

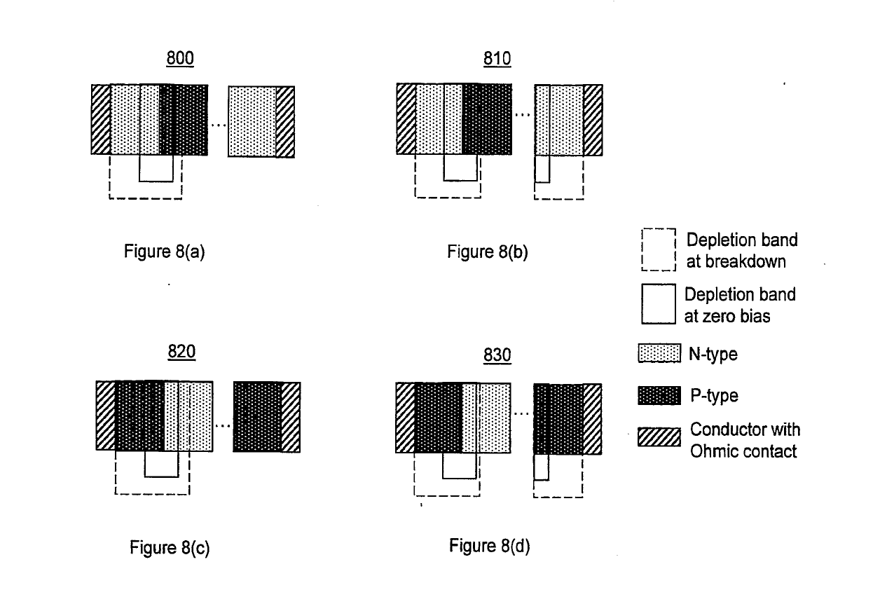

FIGS. 8(a) and 8(c) show NNBD devices 800 and 820 respectively, each having three or more semiconductor regions, one of which being adjacent to a contact; that semiconductor region becomes fully depleted when a Natural breakdown voltage is applied externally. FIGS. 8(b) and 8(d) show NNBD devices 810 and 830 respectively, each having three or more semiconductor regions, two of which each being adjacent to a contact; each of those semiconductor regions become fully depleted when a Natural breakdown voltage is externally applied.

The following steps provide a general method for creating a near natural breakdown Device (NNBD) from a device:

1) Choosing a semiconductor region adjacent to a contact within the device and using the doping concentrations of the device to calculate the width of the depletion region (Zₚ) on the region when the device is not biased. For a near natural condition to be implemented on a semiconductor region of a device with depletion region width Zₚ, the width of the region (Wₚ) needs to be larger than Zₚ.

(2) Using the current width of the region and non-Natural breakdown voltage V_{br} to calculate or simulate the maximum magnitude for the natural breakdown voltage V_{fbr} and using depletion width Zₚ to calculate the minimum value of voltage V_{fbr}. At V_{fbr} bias voltage, the region is fully depleted due to the natural breakdown effect. When the magnitude of V_{fbr} equals the breakdown voltage of a non-natural breakdown condition that occurs within the region, a combination of breakdown effects may occur. When the magnitude of voltage V_{fbr} is less than the breakdown voltage of a non-natural breakdown condition that will occur within the region, only the natural breakdown phenomenon occurs. Also the polarity of V_{fbr} is in the direction of increasing the width of one depletion region within the semiconductor region.

3) Selecting V_{fbr} and calculating a new width of the region (W_{NNBC}) for the NNBD.

A variation of the above general method uses the same step 1) above and the following steps 2) and 3):

2) Determining the maximum and minimum widths of the near natural breakdown region suitable for having a near natural breakdown condition. The maximum width is the smaller value (in magnitude) between the current width of the region and the depletion width across the region at a non-natural breakdown voltage V_{br} which could be calculated or simulated. The minimum value of the region is larger than depletion width Zₚ. Choose a width of the region (W_{NNBC}) between the minimum and maximum width.

3) Calculating V_{fbr} with the selected width W_{NNBC} of the region. At V_{fbr} bias voltage, the region is fully depleted due to the Natural breakdown effect.

The doping concentration and width of a semiconductor region used to create a near natural breakdown condition may be determined once a breakdown voltage has been determined. The doping concentration can be determined by selecting a certain width of the semiconductor region. A limiting factor in determining the doping concentration is that the doping concentration must not create a non-natural breakdown condition (i.e. tunneling) at a voltage with a magnitude less than the decided natural breakdown voltage V_{fbr}. Also the width of the semiconductor region can be determined by selecting a certain doping concentration. The selection of the width must not create a non-natural breakdown condition (e.g. Avalanche) at a voltage with a magnitude less than the selected natural breakdown voltage.

A fully depleted region adjacent a contact in a device at a non-zero applied voltage achieves: (1) Electrons at the contact/semiconductor junction move from fully depleted p-region to the n-region (positive carriers (holes) at the contact/semiconductor junction move from fully depleted n-region to the p-region) as a result of the electric field created by the depletion region. In this case, the distance between the fully depleted p-region and external electrons at the contact/semiconductor junction (the distance between the fully depleted n-region and external positive carriers (holes) at the contact/semiconductor junction) is zero. As a result, a reverse bias conducting current is achieved. (2) If a fully depleted p-region has external electrons at the contact/semiconductor junction (a fully depleted n-region has external positive carriers (holes) at the contact/semiconductor junction), the reverse bias conductivity occurs. (2) If a fully depleted p-region has external electrons at the contact/semiconductor junction (a fully depleted n-region has external positive carriers (holes) at the contact/semiconductor junction), the reverse bias conductivity occurs with a threshold voltage. (3) The electrons at the contact/semiconductor junction move against the direction of the electric field created by the depletion region (the external positive carriers (holes) at the contact semiconductor junction move in the same direction of the electrical field). For example, an NNBD diode conducts at the near natural breakdown voltage, instead of at the avalanche breakdown voltage as in the case of a conventional diode.

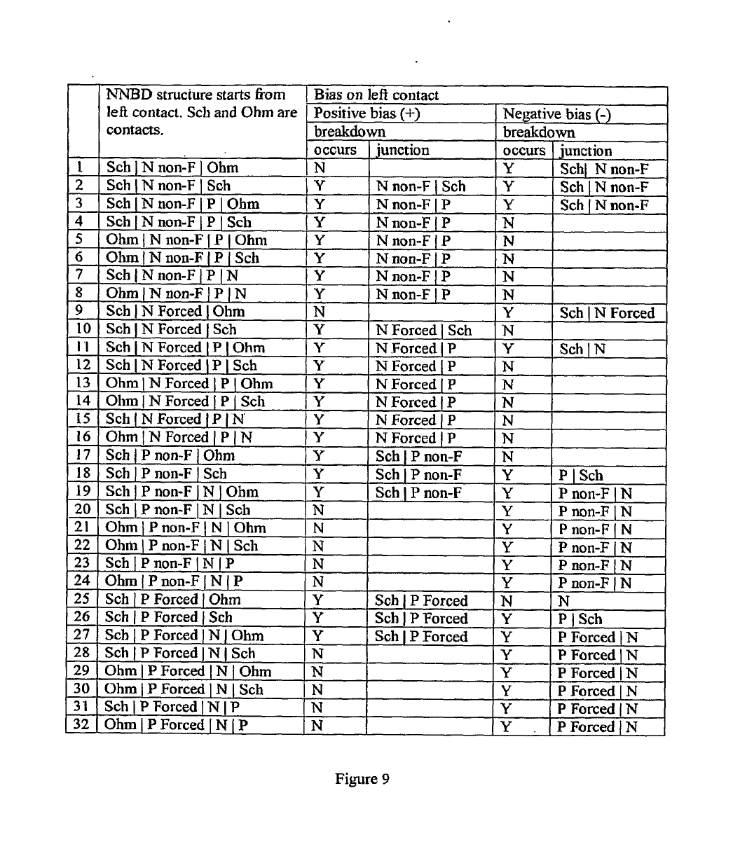

FIG. 9 shows a table of NNBD structures and characteristics under bias voltage, according to the present invention. The first column on the left side of the table is the structure of the NNBD as if the structure where laid out in a linear manner. The terms used to indicate the structure are the following:

“Sch”—Contact-Semiconductor Schottky barrier,

“Ohm”—Contact-Semiconductor Ohmic barrier,

“N non-F”—Non-forced Near Natural breakdown n-type region,

“P non-F”—Non-forced Near Natural breakdown p-type region,

“N Forced”—Forced Near Natural breakdown n-type region,

“P Forced”—Forced Near Natural breakdown p-type region,

“N”—n-type region not under a breakdown condition,

“P”—p-type region not under a breakdown condition,

The second column indicates whether the structure has a forced natural breakdown condition (“Yes”) or not (“No”) when the structure is positively biased on the left side of the structure or negatively biased on the right side of the structure. If the second column indicates a “Yes” the third column then indicates which junction has the forced natural breakdown condition. The forth column indicates whether the structure has a forced natural breakdown condition (“Yes”) or not (“No”) when the structure is negatively biased on the left side of the structure or positively biased on the right side of the structure. If the forth column indicates a “Yes” the fifth column indicates which junction has the forced natural breakdown condition.

NNBD structures in FIG. 9 may be used to derive other NNBD structures that exhibit the near natural breakdown condition characteristics by adding regions and/or utilizing different materials. Some methods to derive other NNBD structures may include, for example, adding an intrinsic material between junctions, using non-homogeneous material or modifications that do not prevent the electric fields from crossing junction. As an example, NNBD structure 29 having a structure “Ohm|P Forced|N|Ohm” may be modified to “Ohm|P Forced|Intrinsic|N|N+|Ohm”.

When an NNBD has a V_{fbr} voltage equal to the non-natural breakdown voltage V_{br}, the combination of the natural breakdown effect and the non-Natural breakdown occurs. The combination of effects utilizes majority carriers during the breakdown conditions, thereby reducing the device capacitance. By reducing the device capacitance, the NNBD can have a shorter turn-off switching time than a device utilizing one breakdown effect, for example, the Avalanche breakdown or the Zener breakdown.

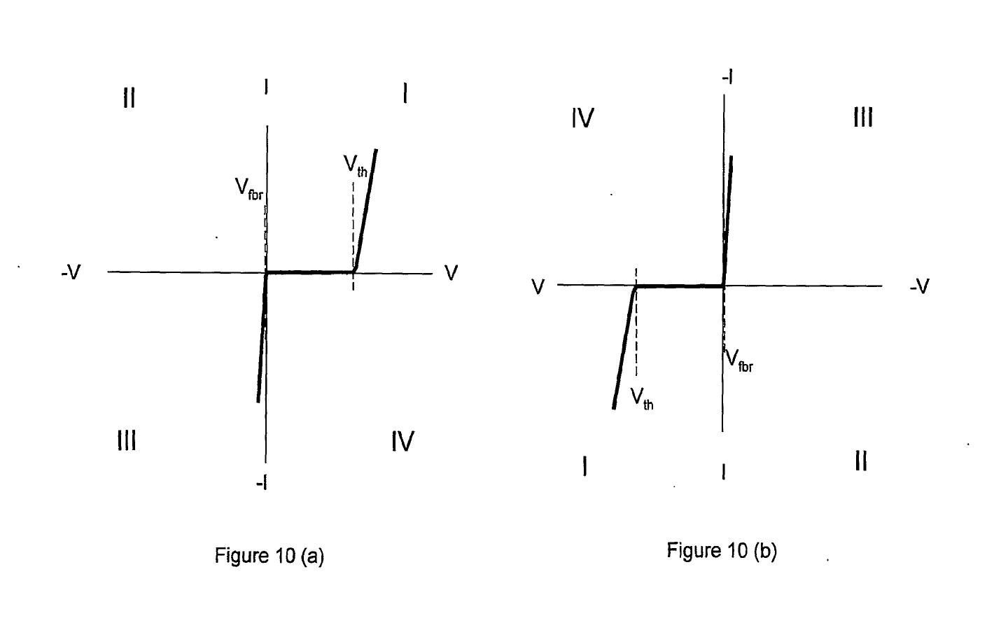

When V_{fbr} is set to a very small value, very close to zero bias, the breakdown condition of an NNBD can be considered having a near-zero forward threshold voltage. For example, NNBD 300 conducts current when it is biased by a near-zero reverse bias voltage (fully depleted). The built-in voltage and V_{fbr} are both used to create a current for NNBD 300. The current is significantly large, such that the resistance on the device need not be a concern. FIG. 10 (a) and FIG. 10 (b) show IV curves of NNBD 300, when the V_{fbr} is at its smallest bias voltage (near-zero) to create a natural breakdown condition on p-region 301. FIG. 10 (a) shows the IV curve of NNBD 300 in forward current and forward bias voltage. FIG. 10 (b) expresses the IV curve of NNBD 300 in reverse current and reverse bias voltage. FIG. 10 (b) shows that NNBD 300 has a reverse breakdown condition at the forward threshold voltage and near-zero forward threshold voltage. When a natural breakdown voltage V_{fbr} is set to a small value, very close to zero, an NNBD conducts current at a near zero threshold voltage and functions like an ideal semiconductor device. For example, NNBD 300 has ideal diode characteristics when having an external applied voltage smaller than the forward bias voltage (Vₜₕ). FIG. 10 (a) and FIG. 10 (b) show the ideal diode IV curve includes the forward bias region from zero to less than Vₜₕ and the entire reverse bias region.

Applications for NNBD diodes include clipping, clamping, voltage regulating, or in applications requiring a predetermined voltage level. Connecting multiple NNBD diodes in parallel will increase the total amount current that flow through the circuit. Connecting multiple NNBD diodes in series will increase the magnitude of the voltage required to create a Natural breakdown condition.

An NNBD diode may be configured to have the depletion region fully extend across both the p-region and n-region at the V_{fbr} voltage so that there are no neutral regions within the device at the breakdown condition. Having no neutral regions during the Natural breakdown condition may increase the switching speed from a non-conducting (off) to a conducting (on) condition. This is because the transit time needed for carriers to cross a neutral region is zero. Also the transit time for carriers to across the depletion region is faster than the transit time for carriers across a neutral region per unit length.

The V_{fbr} voltage is based upon the number of ions within the natural breakdown region. The distribution of these ions within the semiconductor region does not change the natural breakdown voltage V_{fbr}. The number of ions required for creating a V_{fbr} breakdown voltage may be calculated using homogeneous material and the abrupt pn-junction approximation. Once the required number of ions is calculated the distribution of the ions may be chosen to best fit the desired application. The distribution of ions within a natural breakdown region for NNBDs maybe more flexible than other devices using tunneling to create a breakdown including using the Zener effect. This is because tunneling requires a specific doping concentration unlike natural breakdown regions. An example would be having a higher concentration of ions near the adjacent contact to reduce the contact/semiconductor junction resistance. Ion implantation may be used to control the number of ions within a semiconductor region.

A breakdown due to tunneling (i.e. Zener effect) requires having a specific doping concentration. A breakdown due to the Avalanche effect requires specific electric field strength based upon the semiconductor material used. A breakdown caused by the natural breakdown condition only depends on the number of carriers within the fully depleted semiconductor region allowing more flexibility to distribute the carries as necessary to implement required device parameters.

When biasing a near natural breakdown region within a NNBD of the present invention, the near natural breakdown region's depletion region width increases obeys the following rules:
If the forced near natural breakdown region is not fully depleted, then the forced Near Natural breakdown region does not contribute to the resulting current through the device;
If the forced near natural breakdown region is fully depleted and adjacent to a contact then an electron current flows either from the adjacent contact across the fully depleted forced near natural breakdown region, or into the adjacent contact from the fully depleted forced Near Natural breakdown region. The direction of the electron current is determined by the polarity of the electric field within the forced Near Natural breakdown region.

A near natural breakdown condition may be created using an intrinsic material adjacent to a contact or semiconductor region (p-type or n-type). A near natural breakdown region may be created using a p-type or an n-type material adjacent to an intrinsic material. In another embodiment of the present invention, an NNBD uses a forced near natural breakdown region created by a p-type or an n-type semiconductor region adjacent to at least one intrinsic semiconductor region. In another embodiment of the present invention a NNBD uses a non-forced Near Natural breakdown region created by a p-type or an n-type semiconductor region adjacent to at least one intrinsic semiconductor region.

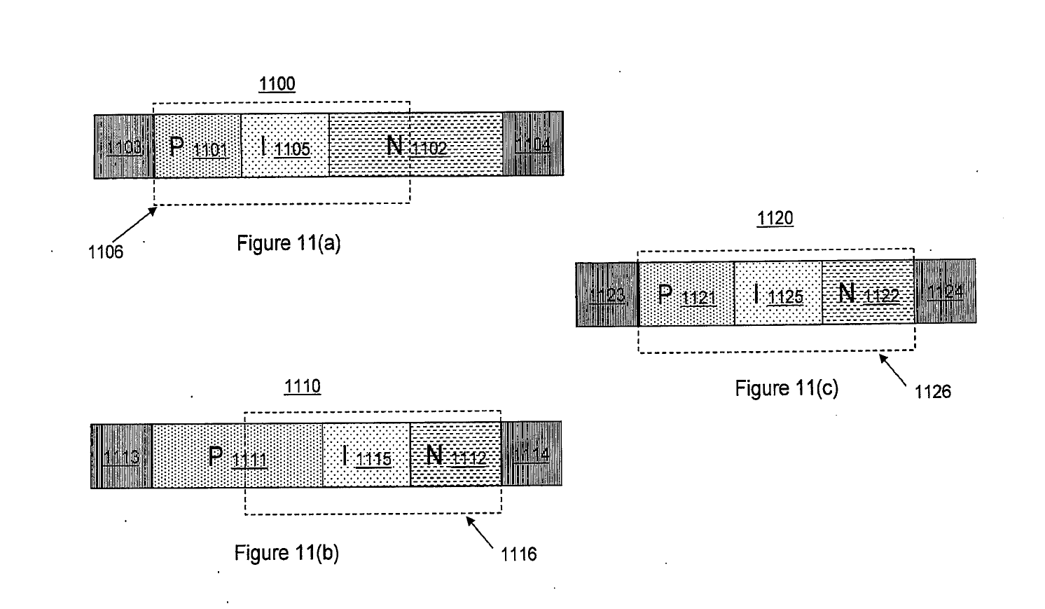

An example of an NNBD created using an existing device utilizing intrinsic material is an NNBD P-I-N diode (i.e., a p-type/intrinsic/n-type diode structure) with one or two forced near natural breakdown regions. FIG. 11(a) shows a schematic representation NNBD 1100, which is an NNBD P-I-N diode having a P-type near natural breakdown region 1101. FIG. 11(b) shows a schematic representation NNBD 1110, which is an NNBD P-I-N diode having an N-type near natural breakdown region 1112. FIG. 11(c) shows a schematic representation NNBD 1120, which is an NNBD P-I-N diode having a P-type near natural breakdown region 1121 and an N-type near natural breakdown region 1122. An NNBD P-I-N diode with one or more semiconductor regions in a near breakdown condition is expected to have faster transit times than a conventional P-I-N diode due to reduced amount of neutral regions.

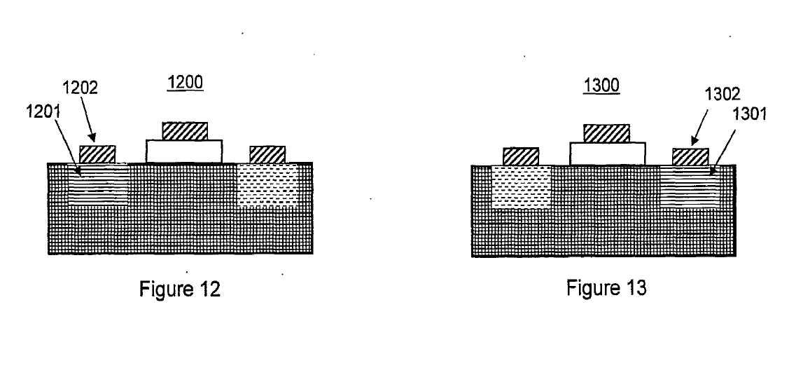

The present invention may be applied to create MOSFET transistors in which the semiconductor regions adjacent source or drain contacts may be provided by near natural breakdown regions. FIG. 13 shows a schematic representation of NNBD 1300, which is an enhancement mode NNBD MOSFET transistor (either an n-channel or p-channel) having a near natural breakdown region 1301 adjacent drain contact 1302. Having a near natural breakdown region adjacent the drain contact in a near natural breakdown condition is expected to shorten transit times due to the depletion region's electric field. FIG. 12 shows a schematic representation of NNBD 1200, which is an enhancement mode NNBD MOSFET transistor (either an n-channel or p-channel) having a near natural breakdown region 1201 adjacent source contact 1202. Having a near natural breakdown region adjacent a source contact in a near natural breakdown condition results in the source depletion region's electric field preventing a channel current from flowing through the NNBD MOSFET device. Such an NNBD MOSFET device may be used for circuit protection.

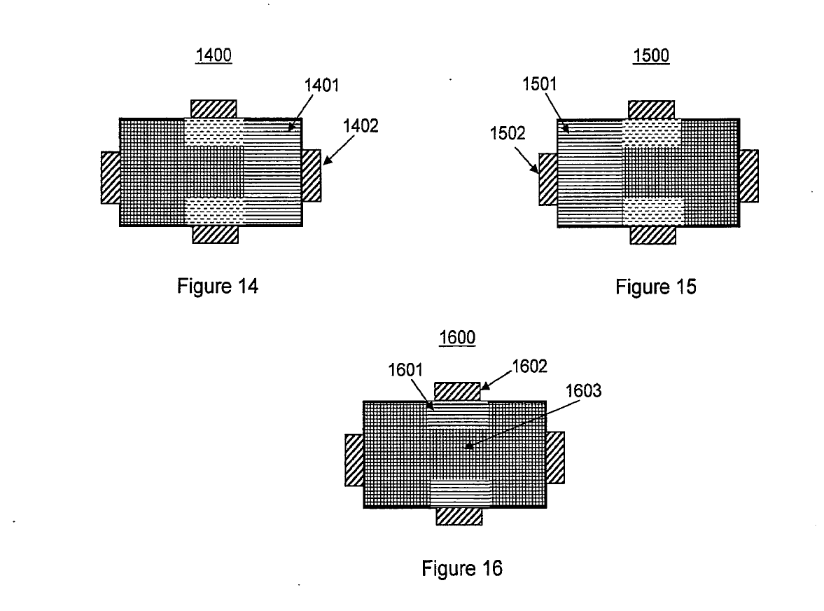

The present invention may also be applied to JFET transistors in which the semiconductor regions adjacent source, drain or gate contacts may be provided as near natural breakdown regions. FIG. 14 shows a schematic representation of NNBD 1400, which is an NNBD JFET transistor (either an n-channel or p-channel) having a near natural breakdown region 1401 adjacent drain contact 1402. Having a near natural breakdown region adjacent to a drain contact in a near natural breakdown condition in expected to shorten transit times, due to the depletion region's electric field. FIG. 15 shows a schematic representation of NNBD 1500, which is an NNBD JFET transistor (either an n-channel or p-channel) having a near natural breakdown region 1501 adjacent source contact 1502. Having a near natural breakdown region adjacent to a source contact in a near natural breakdown condition results in the source depletion region's electric field preventing a current from flowing through the NNBD JFET device. Such an NNBD JFET may be used to create circuit protection.

FIG. 16 shows a schematic representation NNBD 1600, which is an NNBD JFET transistor (either an n-channel or p-channel) having a near natural breakdown region 1601 adjacent gate contact 1602. When near natural breakdown region 1601 is in a near natural breakdown condition, the depletion width formed within the channel 1603 does not change as a result of a change in a gate-to-source voltage, due to the near natural breakdown effect. Also, a current flows from channel 1603 through near natural breakdown region 1601 and out gate contact 1602. Channel 1603 width is not reduced while near natural breakdown region 1601 is in a near natural breakdown condition, thereby allowing NNBD 1600 to achieve a minimum channel width. Such an NNBD device may be used to create circuit protection.

The present invention may be applied to avalanche photodiodes in which the semiconductor region adjacent the contact which receives photons is a non-forced near natural breakdown region. In another embodiment an NNBD avalanche photodiode having a P-type region receiving photons adjacent to a contact be a non-forced near natural breakdown region. Therefore when the NNBD avalanche photodiode is biased at the near natural breakdown voltage the avalanche effect and the near natural breakdown condition both happen together. This may improve noise issues associated with conventional avalanche photodiodes due to the near natural breakdown condition creating a relative constant background current. The NNBD avalanche photodiode background current maybe higher than a conventional avalanche photodiode however the avalanche multiplication which occurs will produce currents significantly larger then the background current once photons are received.

The present invention may be applied to avalanche phototransistors in which the semiconductor region adjacent the collector contact is a non-forced near natural breakdown region. In another embodiment an NNBD avalanche phototransistor has a non-forced natural breakdown region adjacent the collector contact. The NNBD avalanche phototransistor may have the same benefits discussed above for an avalanche photodiode.

The detailed description above is provided to illustrate the specific embodiments above and is not intended to be limiting. Numerous modifications and variations within the scope of the present invention are possible. The present invention is set forth in the following claims.

1-19. (canceled)

20. A semiconductor device, comprising:
a first contact; and
a first semiconductor region having a depleted region having a portion which extends to the first contact at a predetermined bias and is separated from the first contact at zero bias.

21. A semiconductor device as in claim 20, wherein the first semiconductor region is of a first conductivity type, the semiconductor device further comprising a second semiconductor region of a second conductivity type opposite to the first conductivity type.

22. A semiconductor device as in claim 21, wherein the second semiconductor region is completely depleted at the predetermined bias.

23. A semiconductor device as in claim 20, further comprising a conductive material forming a schottky barrier to the first semiconductor region.

24. A semiconductor device as in claim 20, wherein the first semiconductor region is of a first conductivity type, the semiconductor device further comprising:
a second semiconductor region adjacent the first semiconductor region, the second semiconductor region being of a second conductivity type opposite the first conductivity type; and
a third semiconductor region of the first conductivity type adjacent the second semiconductor region.

25. A semiconductor device as in claim 24, wherein the third semiconductor region provides an ohmic contact to the second semiconductor region.

26. A semiconductor device as in claim 20, wherein the first semiconductor region has a width that is less than a width of a depletion band capable of causing the Avalanche effect or Zener effect.

27. A semiconductor device as in claim 20, wherein the first semiconductor region has a width that equals the width of a depletion band capable of causing the Avalanche effect or Zener effect.

28. A semiconductor device as in claim 20, operating as a device selected from the group consisting of (a) a P-I-N diode, (b) a MOSFET, (c) a JFET, (d) an Avalanche Photodiode and (e) an Avalanche Phototransistor.

29. A semiconductor device, comprising:
a first contact and
a first semiconductor region having a first portion of an electric field which is zero value at the first contact at zero bias, and is non-zero value at the first contact at a predetermined bias.

30. A semiconductor device as in claim 29, wherein the first semiconductor region is of a first conductivity type, the semiconductor device further comprising a second semiconductor region of a second conductivity type opposite to the first conductivity type.

31. A semiconductor device as in claim 29, further comprising a metallic region which forms a schottky barrier to the first semiconductor region.

32. A semiconductor device as in claim 29, wherein the first semiconductor region is of a first conductivity type, the semiconductor device further comprising:
a second semiconductor region of a second conductivity type opposite the first conductivity type adjacent the first semiconductor region; and
a third semiconductor region of the first conductivity type adjacent the second semiconductor region.

33. A semiconductor device as in claim 32, wherein the third semiconductor region provides an ohmic contact to the second semiconductor region.

34. A semiconductor device as in claim 29, wherein the first semiconductor region has a width that is less than the width of a depletion band capable of causing the Avalanche effect or Zener effect.

35. A semiconductor device as in claim 34, wherein the first semiconductor region has a width that equals the width of a depletion band capable of causing the Avalanche effect or Zener effect.

36. A semiconductor device as in claim 29, operating as device selected from the group consisting of (a) a P-I-N diode, (b) a MOSFET, (c) a JFET, (d) an Avalanche Photodiode and (e) an Avalanche Phototransistor.

37. A method for providing a natural breakdown condition within a semiconductor device, comprising:
choosing a semiconductor region adjacent to a contact having a depletion band that increases in size when a bias voltage is applied;
choosing a natural breakdown voltage at which a portion of the depletion band reaches the contact and which is less than a voltage that causes an Avalanche or Zener breakdown in the semiconductor device;
determining a width of the depletion band at the natural breakdown voltage;
providing in the semiconductor device a first semiconductor region having a width that equals the determined width.

38. A method to conduct current at a bias voltage, comprising:
providing a first contact; and
providing a first semiconductor region having a depleted region therein, a portion of the depletion region extending to the first contact at a predetermined bias voltage and being separated from the first contact at zero bias.
